(19) United States
(12) Patent Application Publication
(10) Pub. No.: US 2017/0048998 A1
(43) Pub. Date: Feb. 16, 2017

(54) POLYHEDRAL MODULE DEVICE FOR ELECTRONIC MODULAR ASSEMBLY AND METHOD FOR ASSEMBLING ELECTRONIC MODULAR ASSEMBLY USING POLYHEDRAL MODULE DEVICE

(71) Applicant: Seung Chul LEE, Seoul (KR)

(72) Inventor: Seung Chul LEE, Seoul (KR)

(21) Appl. No.: 15/306,375

(22) PCT Filed: Jul. 7, 2014
(86) PCT No.: PCT/KR2014/006048

§ 371 Date: Oct. 24, 2016

(30) Foreign Application Priority Data
Apr. 22, 2014 (KR) 10-2014-0048205

(51) Int. Cl. H05K 5/02; H05K 5/00; G06F 1/16

(52) U.S. Cl. CPC H05K 5/0256; G06F 1/16; H05K 5/0021; G06F 2200/1635

(57) ABSTRACT

A polyhedral module device includes a body having multiple outer faces; a plurality of outer electrical contacts on at least one outer face of the body; an internal circuit mount disposed in the body; a specific-purpose internal circuit mounted on the mount; a switch network disposed in the body, the network having a plurality of switches, connections between the plurality of switches in the network being flexible; and a switch controller configured to change the connections between the plurality of switches, wherein the change of the connections between the plurality of switches by the switch controller changes connection paths between the outer electrical contacts and the internal circuit.

### CROSS-REFERENCE TO RELATED APPLICATION

This application claims the benefit of Korea Patent Application No. 10-2014-0048205 filed on Apr. 22, 2014, the entire content of which is incorporated herein by reference for all purposes as if fully set forth herein.

### BACKGROUND

Field of the Present Disclosure

The present disclosure relates to a polyhedral module device for an electronic modular assembly and a method for assembling an electronic modular assembly using the polyhedral module device. More particularly, the present disclosure relates to a polyhedral module device for an electronic modular assembly wherein the device as one functional module of the electronic modular assembly has a specific-purposed internal circuit, and a method for assembling an electronic modular assembly using the polyhedral module device.

Discussion of the Related Art

An electronic modular assembly may have multiple functional modules.

The electronic modular assembly may have the multiple functional modules mounted on a PCB having circuit patterns defined thereon.

Generally, the electronic modular assembly may have a very complicated architecture. Thus, a non-expert may not easily deal with the assembly thereof. Thus, the non-expert may purchase a completely assembled product.

The user may not add, replace or upgrade a desired specific functional module to, for or in the completely assembled product. Thus, the user may purchase a new completely assembled product. This may lead a high cost to the user.

For example, PC may be more familiar with non-experts in terms of assembly thereof over the electronic modular assembly because modular components may be fitted into sockets on the main board of the PC. Nevertheless, the user should know accurate locations of the modular components on the PC main board. Further, the user should know connections between various wires. Thus, the assembly of the PC may be not easy for the person unfamiliar with the PC architecture.

Further, the sockets on the main board in the PC have been standardized to correspond to modular components with specific sizes. Thus, new modular components out of the sizes may not be fitted into the sockets.

For example, a new VGA card is available in the marketplace. The user may intend to replace the old one with the new one in the PC. However, when the existing main board does not support the new VGA card, a new main board should be obtained.

### SUMMARY

From considerations of the above situations, the present disclosure provides a polyhedral module device for an electronic modular assembly to allow the person unfamiliar with a special knowledge of an architecture of the electronic device to easily upgrade or replace or assembly the electronic modular assembly.

Further, from considerations of the above situations, the present disclosure provides a method for assembling the electronic modular assembly using the polyhedral module device.

Furthermore, from considerations of the above situations, the present disclosure provides a computer readable medium including instructions which are executed by a computer to allow the computer to perform the above method.

In an aspect of the present disclosure, there is provided a polyhedral module device, the device comprising: a body having multiple outer faces; a plurality of outer electrical contacts on at least one outer face of the body; an internal circuit mount disposed in the body; a specific-purpose internal circuit mounted on the mount; a switch network disposed in the body, the network having a plurality of switches, connections between the plurality of switches in the network being flexible, the switch network being configured to electrically connect the internal circuit to the outer electrical contact; and a switch controller configured to change the connections between the plurality of switches, wherein the change of the connections between the plurality of switches by the switch controller changes connection paths between the outer electrical contacts and the internal circuit.

In one embodiment, the polyhedral module device further comprises: an internal circuit information storage configured to store therein internal circuit connection information to indicate connections of an input and an output of the internal circuit; a communication unit configured to communicate with an external device via a fixed path, wherein the fixed path is formed between the electrical contact and the communication unit, wherein in response to a receipt of the internal circuit connection information request from the external device, the communication unit is configured to send the internal circuit connection information from the storage via the fixed path to the external device.

In one embodiment, the communication unit is further configured to send signal transfer path information to the external device along with the internal circuit connection information, wherein the signal transfer path information indicates a path along which a single containing the internal circuit connection information travel.

In one embodiment, the signal transfer path information further includes first identification information about the polyhedral module device and second identification information to indicate an outer face associated with the fixed path.

In one embodiment, the polyhedral module device further comprises a communication unit configured to communicate with an external device via a fixed path, wherein the fixed path is formed between the electrical contact and the communication unit, wherein the polyhedral module device defining a first polyhedral module device communicates with a further polyhedral module device defining a second polyhedral module device, the communication unit is configured to receive a first signal from the second polyhedral module device and output a second signal, wherein the second signal includes, in addition to the first signal, identification information to indicate an outer face of the first polyhedral module device through which the first signal is input, and identification information of the first polyhedral module device, and identification information to indicate an outer face of the first polyhedral module device through which the second signal is output.

In one embodiment, the communication unit is configured to determine a position and orientation of the second polyhedral module device using the first signal, wherein the communication unit is configured to set a signal transmission path using the position and orientation of the second polyhedral module device in order to send a signal to the second polyhedral module device.

In one embodiment, the polyhedral module device further comprises physical couplers formed on the outer face of the polyhedral module device.

In one embodiment, the polyhedral module device further comprises: an internal circuit information storage configured to store therein identification and/or connection information of the internal circuit; and a communication unit configured to communicate with an external device via a fixed path, wherein the fixed path is formed between the electrical contact and the communication unit, when the communication unit receives a request for the internal circuit identification and/or connection information from the external device, the communication unit is configured to send the identification and/or connection information of the internal circuit via the fixed path to the external device.

In an aspect of the present disclosure, there is provided a method for assembling a modular electronic assembly with a plurality of polyhedral module devices, wherein each polyhedral module device comprises: a body having multiple outer faces; a plurality of outer electrical contacts on at least one outer face of the body; an internal circuit mount disposed in the body; a specific-purpose internal circuit mounted on the mount; a switch network disposed in the body, the network having a plurality of switches, connections between the plurality of switches in the network being flexible, the switch network being configured to electrically connect the internal circuit to the outer electrical contact; a communication unit configured to communicate with an external device via a fixed path, wherein the fixed path is formed between the electrical contact and the communication unit, an internal circuit information storage configured to store therein identification information of the internal circuit; and a switch controller configured to change the connections between the plurality of switches, wherein the change of the connections between the plurality of switches by the switch controller changes connection paths between the outer electrical contacts and the internal circuit, wherein the method comprises: receiving, by the communication unit, a request for the internal circuit identification information from the external device; sending, by the communication unit, signal transfer path information along with the identification information of the internal circuit to the external device, wherein the transfer path information indicates a path along which the identification information of the internal circuit travels; receiving, by the communication unit, from the external device, connections between the plurality of switches configured based on the signal transfer path information and the identification connection information of the internal circuit; and changing, by the switch controller, actually changing the connections between the plurality of switches based on the received connections between the plurality of switches from the external device.

In an aspect of the present disclosure, there is provided a polyhedral module device as a member of a modular electronic assembly, wherein the device comprises: a body; a specific-purposed internal circuit in the body; an internal circuit mount to mount the internal circuit in the body; an internal circuit information storage to store therein information about the internal circuit; an other-module information storage configured to store therein other-module information, wherein the other-module information includes signal transmission path information and destination identification information, wherein the signal transmission path information indicates which path is used to send a signal output from an output of the internal circuit in order to operate the electronic modular assembly, and the destination identification information indicates a destination to which the signal is directed; a communication unit configured to communicate with another device wirelessly; and a signal transfer unit configured to add the other-module information in the other-module information storage to the signal from the output of the internal circuit and to transfer the signal to the communication unit.

In an aspect of the present disclosure, there is provided a method for assembling a modular electronic assembly with a plurality of polyhedral module devices, wherein each polyhedral module device comprises: a body; a specific-purposed internal circuit in the body; an internal circuit mount to mount the internal circuit in the body; an internal circuit information storage to store therein information about the internal circuit; an other-module information storage configured to store therein other-module information, wherein the other-module information includes signal transmission path information and destination identification information, wherein the signal transmission path information indicates which path is used to send a signal output from an output of the internal circuit in order to operate the electronic modular assembly, and the destination identification information indicates a destination to which the signal is directed; a communication unit configured to communicate with another device wirelessly; and a signal transfer unit configured to add the other-module information in the other-module information storage to the signal from the output of the internal circuit and to transfer the signal to the communication unit, wherein the method comprises: receiving, by the communication unit, a request of the internal circuit connection information; sending, by the communication unit, the internal circuit connection information wirelessly; receiving the other-module information configured based on the internal circuit connection information; and adding, by the signal transfer unit, the other-module information in the other-module information storage to the signal from the output of the internal circuit and transferring the signal to the communication unit.

In an aspect of the present disclosure, there is provided a polyhedral module device comprising: a body having multiple outer faces; an internal circuit mount disposed in the body; a specific-purpose internal circuit mounted on the mount; a switch network disposed in the body, the network having a plurality of switches, connections between the plurality of switches in the network being flexible; a switch controller configured to change the connections between the plurality of switches and/or change a connection in each switch based on switch control information; wherein the change of the connection in each switch enables or disables a connection between input and output terminals of the internal circuit.

In an aspect of the present disclosure, there is provided a method for assembling a modular electronic assembly with a plurality of polyhedral module devices, wherein each polyhedral module device comprises: a body having multiple outer faces; an internal circuit mount disposed in the body; a specific-purpose internal circuit mounted on the mount; a switch network disposed in the body, the network having a plurality of switches, connections between the plurality of switches in the network being flexible; a switch controller configured to change the connections between the plurality of switches and/or change a connection in each switch based on switch control information; wherein the change of the connection in each switch enables or disables a connection between input and output terminals of the internal circuit, wherein the method comprises: receiving the switch control information; and changing the connection in each switch based on the switch control information to enable or disable a connection between the input and output terminals of the internal circuit.

In an aspect of the present disclosure, there is provided a computer readable medium including instructions which are executed by a computer to allow the computer to perform the above-defined method.

In accordance with the present disclosure, the non-expert user may simply add or assembly the present polyhedral module device into the complete modular assembly in order to upgrade or repair the complete modular assembly by connecting the polyhedral module device to an adaption-support external system to support the adaption of the connection for the inner circuit.

Thus, the non-expert user may select a desired functional module and add the polyhedral module device corresponding to the desired functional module to the complete modular assembly to add the new component or upgrade the old components easily.

### BRIEF DESCRIPTIONS OF THE DRAWINGS

FIG. 1 shows a perspective view of a polyhedral module device in accordance with one embodiment of the present disclosure.

FIG. 2 shows a combination of plural present polyhedral module devices.

FIG. 3 shows a side view for describing an outer face of the present polyhedral module device.

FIG. 4 shows a side view for describing a physical coupling between adjacent present polyhedral module devices.

FIG. 5 shows a bock diagram of the present polyhedral module device in which functional blocks are connected via lines.

FIG. 6 shows fixed electrical paths for realizing communication of the present polyhedral module device.

FIG. 7 shows a high level diagram of the polyhedral module device having an outer layer, an intermediate layer, and an inner layer.

FIG. 8 shows a flow diagram of changing operations of the connections between the switches.

FIG. 9 shows fixed power supply paths for polyhedral module devices.

FIG. 10 shows a high level diagram of a switch network in accordance with one embodiment of the present disclosure.

FIG. 11 shows a bottom power supply mount to be coupled to the present polyhedral module devices to supply the power thereto.

FIG. 12 shows a single external case receiving therein a combination of a plurality of polyhedral module devices.

FIG. 13 shows a block diagram for explaining a configuration where the present polyhedral module device sends a signal wirelessly.

FIG. 14 shows one example of a method for setting a signal path when the present polyhedral module device transmits the signal wirelessly.

### DETAILED DESCRIPTIONS

Examples of various embodiments are illustrated in the accompanying drawings and described further below. It will be understood that the description herein is not intended to limit the claims to the specific embodiments described. On the contrary, it is intended to cover alternatives, modifications, and equivalents as may be included within the spirit and scope of the present disclosure as defined by the appended claims. Example embodiments will be described in more detail with reference to the accompanying drawings. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art.

For simplicity and clarity of illustration, elements in the figures are not necessarily drawn to scale. The same reference numbers in different figures denote the same or similar elements, and as such perform similar functionality. Also, descriptions and details of well-known steps and elements are omitted for simplicity of the description. Furthermore, in the following detailed description of the present disclosure, numerous specific details are set forth in order to provide a thorough understanding of the present disclosure. However, it will be understood that the present disclosure may be practiced without these specific details. In other instances, well-known methods, procedures, components, and circuits have not been described in detail so as not to unnecessarily obscure aspects of the present disclosure.

Hereinafter, embodiments of the present disclosure will be described in details with reference to attached drawings.

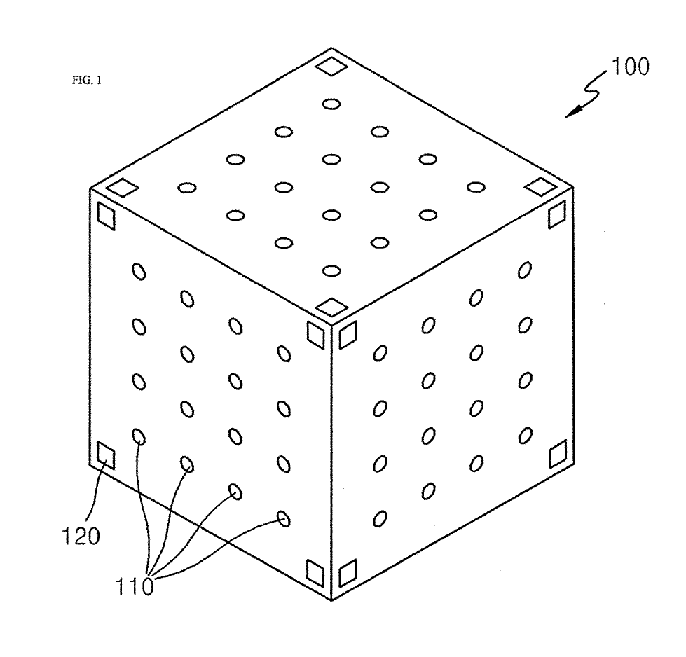

FIG. 1 shows a perspective view of a polyhedral module device in accordance with one embodiment of the present disclosure.

The present polyhedral module device 100 may have a special-purposed circuit therein formed therein. The polyhedral module device may be plural which may be interconnected to form a modular complete device.

Referring to FIG. 1, the present polyhedral module device 100 may have a cubic shape. The present disclosure may be not limited thereto. The present polyhedral module device 100 may have different polyhedral shapes including hexagonal column, octagonal column, octahedral shapes. Adjacent polyhedral module devices may be interconnected at adjacent side faces thereof.

Further, all of the polyhedral module devices may not necessarily have the same shape. The polyhedral module devices with different shapes may be interconnected at adjacent side faces thereof.

As shown in FIG. 1, the present polyhedral module device 100 may have a plurality of outer electrical contacts formed on each side face thereof. The present polyhedral module device 100 may have physical couplers 120 configured to couple the current polyhedral module device 100 to another current polyhedral module device.

The number and/or positions of the outer electrical contacts 110 and number and/or positions of the physical couplers 120 may vary depending on a designer's choice of a complete modular device.

The outer electrical contacts 110 may be made of an electrically conductive material. The outer electrical contacts 110 may contact an external device, especially, corresponding outer electrical contacts of another polyhedral module device respectively.

The outer electrical contacts 110 may protrude from each outer face of the polyhedral module device in order to realize an electrical connection with another polyhedral module device. The present disclosure may not be limited thereto. The outer electrical contacts 110 may protrude from each outer face of the polyhedral module device as long as they contact outer electrical contacts of another polyhedral module device.

The physical couplers 120 may act to realize a physical coupling between adjacent polyhedral module devices.

The physical couplers 120 may act to realize a physical coupling between adjacent polyhedral module devices. The present disclosure may not be limited thereto. The physical couplers 120 may also act to realize a physical coupling between the polyhedral module device 100 and another external device which is not an attribute of the polyhedral module device.

For example, when the present polyhedral module device 100 is housed in a case for an electric device, the physical couplers 120 may act to realize a physical coupling between the polyhedral module device 100 and the case.

Further, in this connection, the polyhedral module device 100 may be fixed to the case via the couplers. Thus, the polyhedral module device 100 may not have physical couplers used to realize a physical coupling to another polyhedral module device. In one embodiment, when the polyhedral module device 100 is directly fixed to the case, it may dispense with the physical couplers 120.

In other words, the polyhedral module devices may be physically coupled to each other using the physical couplers 120 without aids of the external device. The present disclosure may not be limited thereto. When the polyhedral module device is directly fixed to the external device such as the case, the physical couplers 120 may be omitted.

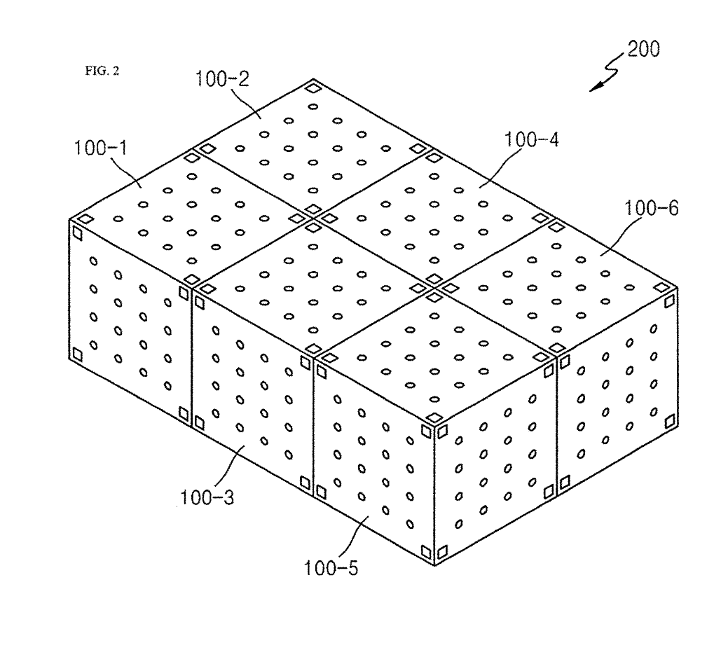

FIG. 2 shows a combination 200 of plural present polyhedral module devices 100-1, 100-2, 100-3, 100-4, 100-5, 100-6.

As shown in FIG. 2, a complete modular electronic modular assembly may be achieved by simply arranging and coupling the polyhedral module devices. Thus, a non-expert unfamiliar with a special knowledge on an electronic modular assembly fabrication may easily make up the complete modular electronic modular assembly.

When the complete modular electronic modular assembly as shown in FIG. 2 may be achieved, the complete modular electronic modular assembly may be entirely received in the case for an electronic modular assembly package or may be connected to another electronic modular assembly in use.

The combination 200 of the present polyhedral module devices may be applied to any attribute of an electric device.

In particular, the present polyhedral module device may be applied to a multi-function electric device such as PC or smartphone, etc. in which a plurality of functional modules is incorporated to execute each function. In this connection, when a single functional module needs to be changed or replaced in the multi-function electric device, the present polyhedral module device functionally corresponding to the single functional module may be added into the multi-function electric device. This may lead to easy upgrade or addition or replacement of some functional modules.

Now, a configuration of an outer face of the polyhedral module device 100 will be described in details.

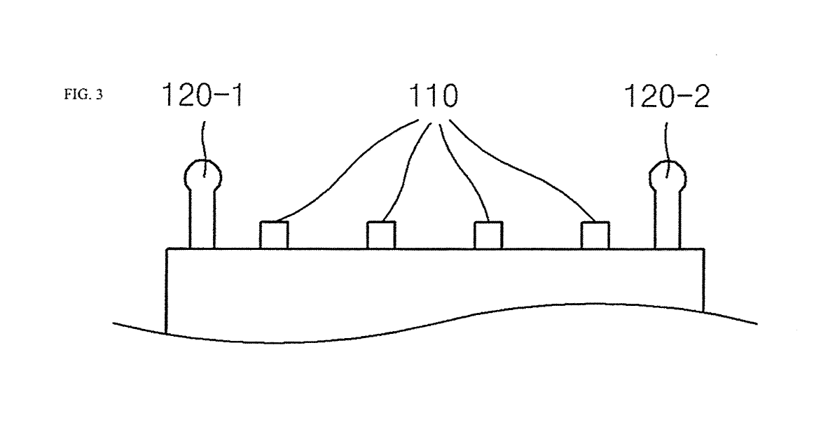

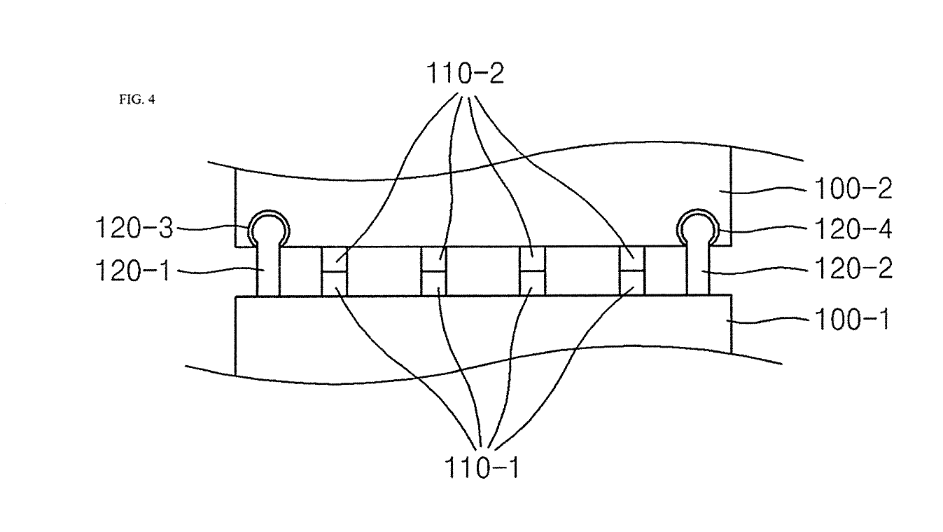

FIG. 3 shows a side view for describing an outer face of the present polyhedral module device. FIG. 4 shows a side view for describing a physical coupling between adjacent present polyhedral module devices.

From the outer face of the polyhedral module device, outer electrical contacts 110 may protrude as shown in FIG. 3. The outer electrical contacts 110 of one polyhedral module device may contact outer electrical contacts of another polyhedral module device.

As shown in FIG. 4, when one polyhedral module device 100-1 is coupled to another polyhedral module device 100-2, the outer electrical contacts 110-1 of the polyhedral module device 100-1 may contact outer electrical contacts 110-2 of the polyhedral module device 100-2.

The outer electrical contacts 110 may be made of an electrically conductive material such as a copper, gold, silver, etc. Thus, when the polyhedral module device 100-1 is coupled to the polyhedral module device 100-2, the outer electrical contacts 110-1 of the polyhedral module device 100-1 contact the outer electrical contacts 110-2 of the polyhedral module device 100-2, thereby to realize a electrical connection between the polyhedral module device 100-1 [symbol] polyhedral module device 100-2.

The polyhedral module device 100-1 may be physically coupled to the polyhedral module device 100-2 using the physical couplers 120-1, 120-2, 120-3, 120-4.

As shown in FIG. 4, the physical couplers 120-1, 120-2 of the polyhedral module device 100-1 may protrude outwardly. The physical couplers 120-3, 120-4 of the polyhedral module device 100-2 may be recessed inwardly. Thus, the physical couplers 120-1, 120-2 of the polyhedral module device 100-1 may be engaged with the physical couplers 120-3, 120-4 of the polyhedral module device 100-2 respectively.

A different configuration from in FIG. 3 and FIG. 4 may be applied to the outer electrical contacts 110 and physical couplers 120.

For example, as shown in FIG. 3 and FIG. 4, the outer electrical contacts 110 may protrude from each outer face of the module device. The present disclosure may not be limited thereto. the outer electrical contacts of one polyhedral module device may protrude from each outer face of the module device while the outer electrical contacts of another neighboring polyhedral module device may be recessed therein. In this connection, it may dispense with the physical couplers.

Further, the physical couplers may be made of a magnetic material. Thus, the physical couplers may not protrude or be recessed to realize the fixed coupling between adjacent polyhedral module devices.

In this way, the outer electrical contacts may realize an electric connection between adjacent polyhedral module devices. The physical couplers may realize a physical connection between adjacent polyhedral module devices.

At least one outer face of the present polyhedral module device may have the outer electrical contacts as shown in FIG. 3 and FIG. 4.

All of outer faces of the present polyhedral module device may have the plurality of outer electrical contacts. This may realize the combination of the polyhedral module devices as shown in FIG. 2 in an independent manner from alignments of outer faces with the contacts of the polyhedral module devices. The present disclosure may not be limited thereto. each of the outermost polyhedral module devices 100-1, 100-2, 100-5, 100-6 in the combination 200 of FIG. 2 may have only two outer faces with the outer electrical contacts. In an alternative, each polyhedral module device may have only one outer face with the outer electrical contacts.

Further, when it is intended that adjacent polyhedral module devices are not coupled to each other but polyhedral module devices are coupled to another external device such as the case, each polyhedral module device may have only the coupled outer face with the outer electrical contacts.

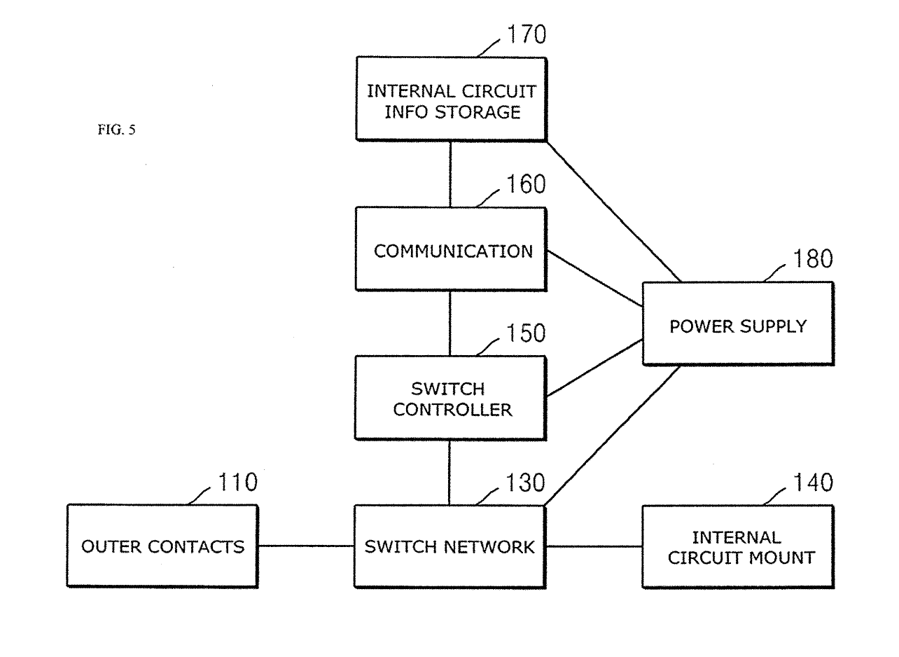

The present polyhedral module devices may be combined to each other regardless of a combination sequence or position to achieve the target complete modular electronic modular assembly. This may be discussed with reference to FIG. 5.

FIG. 5 shows a bock diagram of the present polyhedral module device in which functional blocks are connected via lines.

The present polyhedral module device 100 may include outer electrical contacts 110, physical couplers (not shown), a switch network 130, an internal circuit mount 140, a switch controller 150, a communication unit 160, an internal circuit information storage 170, and a power supply 180.

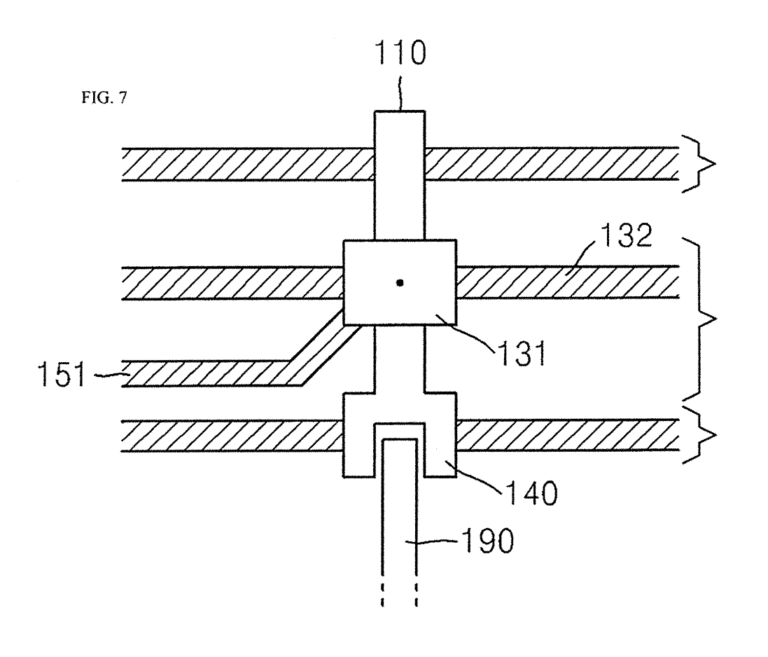

As shown in FIG. 7, the polyhedral module device 100 may have an outer layer, an intermediate layer, and an inner layer. The outer layer may have the outer electrical contacts 110, and the physical couplers (not shown). The inner layer may have the internal circuit mount 140. The intermediate layer may have the switch network 130 with switches 131 which may switch-connect the outer electrical contacts 110 and internal circuit mount 140 with each other.

The remaining components may be located at predetermined positions in the polyhedral module device. The remaining components may not be limited specifically in positions thereof as long as electrical connections thereto are available.

As described above, the outer electrical contacts 110 in the outer layer may be electrically connected to another external device and may receive or send an electrical signal from or to the external device.

The outer electrical contacts 110 may be connected to the switch 131.

The switch 131 may be configured to control connections between electrical paths coupled thereto under control of the switch controller 150.

The plurality of switches may form the switch network 130 which may be located in the intermediate layer of the polyhedral module device. The configuration of the switch network 130 may correspond to an overall connection between the signal communication paths.

Via the switch network 130, a signal from the external device may be transferred to the internal circuit and/or further to another external device.

It may be preferable that a single outer electrical contact 110 is connected to a single switch 131 except for an outer electrical contact at a fixed communication path.

However, the present disclosure may not be limited thereto. A single outer electrical contact may be connected to at least two switches. Alternatively, a single switch may be connected to at least two outer electrical contacts.

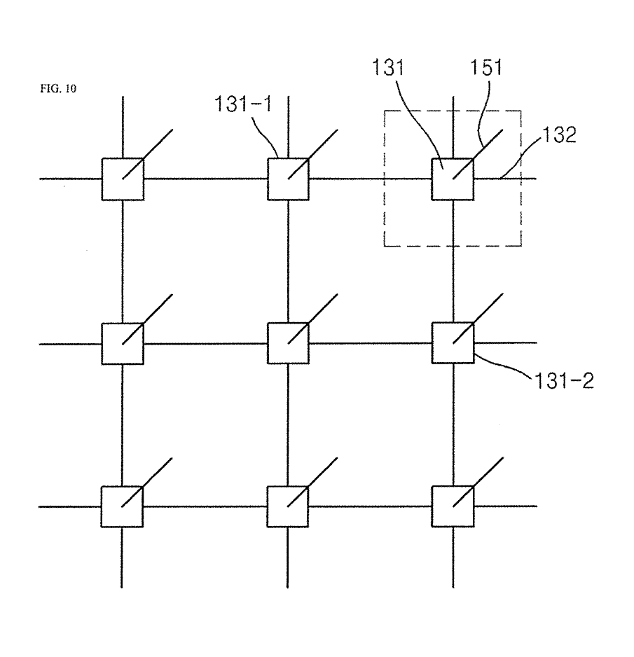

With reference to FIG. 7 and FIG. 10, the switch network 130 and switch 131 will be described below.

FIG. 10 shows a high level diagram of a switch network in accordance with one embodiment of the present disclosure.

As shown in FIG. 7 and FIG. 10, the switch network may include plural switches interconnected via an electrical path 132. The outer electrical contacts 110 and internal circuit mount 140 may be connected via the switch network.

The switch 131 may receive switch control information from the switch controller 150 via the switch control information transmission electrical path 151. The switch control information may control the connections within the internal circuit.

To be specific, in a signal transmission via the switch 131-1, switch control information from the switch controller 150 to the switch 131-1 may determine whether the signal goes to the switch 131-2 or the outer electrical contact 110, or the internal circuit mount 140. Further, the switch control information from the switch controller 150 may determine whether a signal from the outer electrical contact 110 goes the switch 131-1 or the switch 131-2 or the internal circuit mount 140.

The details about setting internal connections in the switch using the control signal are well known to the skilled person to the art, and, thus, may be omitted.

In FIG. 10, the switch network forms a single layer. The present disclosure may not be limited thereto. the switch network may form multiple layers.

An increase in the number of polyhedral module devices to be combined may cause difficulty in securing paths for connecting polyhedral module devices. For this reason, the switch network may have additional switches to secure the number of variable paths.

On the internal circuit mount 140, a specific-purposed internal circuit may be mounted. The internal circuit mount 140 may connect input/output terminals of the internal circuit 190 and the switch 131 of the switch network 130.

The internal circuit may include a circuit board including a graphic card, a sound card, etc. or may include a specific-purposed electric device such as CPU, etc. or may include a power supply device such as a battery.

In order to mount the internal circuit 190 thereon, the internal circuit mount 140 may be embodied as a socket, slot, etc. However, the internal circuit mount 140 may not be limited thereto. The internal circuit mount 140 may connect input/output terminals of the internal circuit 190 and the switch 131 of the switch network 130.

The internal circuit mount 140 may connect each of the input/output terminals of the internal circuit 190 to at least one switch 131 of the switch network 130. In this way, a signal may reach the target destination via the switch network as shown in FIG. 10.

The switch controller 150 may be configured to control each switch 131 in the switch network 130 to set connection paths in the switch network 130.

Control information to set the connection paths in the switch network 130 may be created by the switch controller 150 or may be received from an external device. This will be described later.

The internal circuit information storage 170 may store therein connection information for the internal circuit.

When manufacturing the present polyhedral module device, a specific purpose of the internal circuit contained in the polyhedral module device is predetermined. In this connection, information on the specific purpose of the internal circuit may be stored in the internal circuit information storage 170.

The connection information for the internal circuit may indicate each of the input/output terminals of the internal circuit is to be connected to which portion of external circuit. The connection information for the internal circuit may be used to set connection paths in the switch network 130.

The connection information for the internal circuit may include an attribute of the internal circuit, information about a position in the internal circuit mount 140 connected to each of the input/output terminals of the internal circuit, information about a switch connected to each of the input/output terminals of the internal circuit, and information on an attribute of a signal to be send to each of the input/output terminals of the internal circuit.

The internal circuit information storage 170 may store therein only the connection information for the internal circuit as described above. The present disclosure may not be limited thereto. The internal circuit information storage 170 may store therein only identification information to indicate a specific purpose or an attribute of the internal circuit.

The connection information for the internal circuit may be unique based on the attribute of the internal circuit, or the attribute of the polyhedral module device. In this connection, the internal circuit connection information may be in advance stored in a data server. Thus, the internal circuit connection information needs not to be stored in the corresponding polyhedral module device. Thus, the internal circuit information storage 170 may store therein only identification information to indicate a specific purpose or an attribute of the internal circuit or polyhedral module device.

In an alternative, some of internal circuit information may be stored in the data sever as an external system, while the rest of the internal circuit information together with the identification information to indicate a specific purpose or an attribute of the internal circuit or polyhedral module device may be stored in the internal circuit information storage 170.

In this connection, identification information to specify the internal circuit or identification information to indicate the attribute of the polyhedral module device may be the same or different.

In order to identify the attribute of the internal circuit and the connection information thereof or identify the polyhedral module device, a single identification may be used. In an alternative, first identification information may be used to identify the attribute of the internal circuit and second identification information may be used to identify the polyhedral module device.

When the first identification information is used to identify the attribute of the internal circuit and the second identification information is used to identify the polyhedral module device, polyhedral module devices with the same attribute internal circuit may be assigned different identification information.

In this way, when a plurality of polyhedral module devices forms a complete modular electronic modular assembly, the polyhedral module devices with the same attribute internal circuit may be individually identified.

At this case, identification information use to indicate the internal circuit connection information may be used as identification information to indicate the attribute of the internal circuit. The identification information to identify the polyhedral module device may be used separately.

Whether in the former or latter, the information stored in the internal circuit information storage 170 to be used to indicate the attribute of the internal circuit and the connection thereof may be referred to as internal circuit identification information.

The communication unit 160 may communicate with an external system or device or sever or user.

The communication unit 160 may use a portion of the switch network 130 for the communication. The present disclosure may not be limited thereto. The communication unit 160 may use fixed communication paths for the communication with an external system or device or sever or user.

A path between the switch 131 and communication unit 160 may vary by controlling an internal connection, while a path between the communication unit 160 and outer electrical contacts 110 may be fixed.

The communication unit 160 may be mainly used to combine the polyhedral module devices and to set initial connection paths in the switch network 130.

Initially, because a sequence or a position reaction of the polyhedral module devices in combining the devices, or a connection configuration in the switch network is unknown, the fixed path should be used to realize the communications between the polyhedral module devices.

For this, at least one outer electrical contact 110 among the plural outer electrical contacts 110 in each outer face should be always connected to the communication unit 160 to form the fixed communication path over which the communication unit 160 may communicate with the external device.

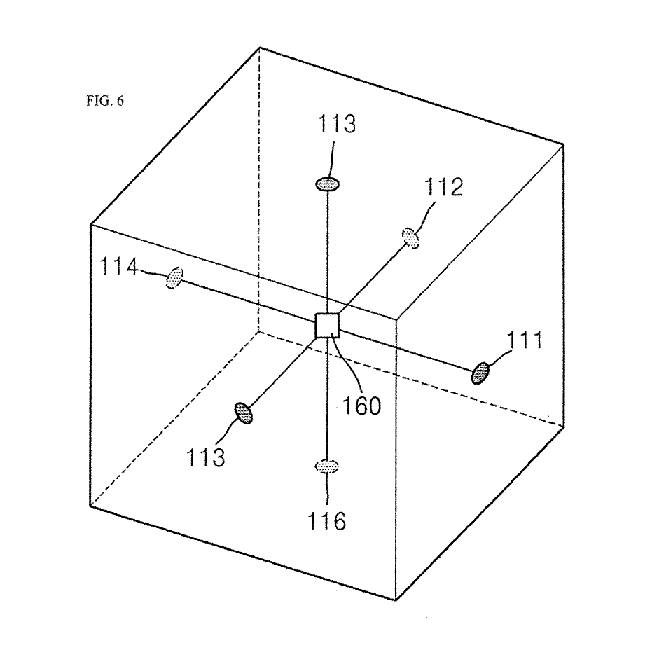

FIG. 6 shows fixed electrical paths for realizing communication of the present polyhedral module device.

As shown in FIG. 6, each outer face of polyhedral module device may have each of outer electrical contacts 111, 112, 113, 114, 115, 116 which may be commonly connected to the communication unit 160.

In FIG. 6, for the sake of convenience of illustration, the communication unit 160 is shown to be centrally located in the polyhedral module device. The present disclosure may not be limited thereto. The communication unit 160 may be located in any position in the polyhedral module device and the outer electrical contacts 111, 112, 113, 114, 115, 116 may be commonly connected to the communication unit 160 to form fixed paths.

It may be preferable that each of the outer electrical contacts commonly connected to the communication unit 160 is centrally disposed in each outer face of the polyhedral module device.

This may allow each outer electrical contact in each outer face of the polyhedral module device to always contact an outer electrical contact of an adjacent polyhedral module device when the polyhedral module device is rotated.

It may be preferable that each of the outer electrical contacts commonly connected to the communication unit 160 is centrally disposed in each outer face of the polyhedral module device. The present disclosure may not be limited thereto. A position of each outer electrical contact of each outer face of the polyhedral module device may vary depending on a designer's choice.

For example, each outer electrical contact may be located at each of all corners of each outer face of the polyhedral module device. In this connection, although the polyhedral module device is rotated, each outer electrical contact at each corner in each outer face of the polyhedral module device always contacts one outer electrical contact at one corner in one outer face of an adjacent polyhedral module device. When the polyhedral module device has a cubic structure, four outer electrical contacts may be disposed at four corners of each outer face of the polyhedral module device respectively to form fixed paths with the communication unit.

The communication unit 160 may send information in the internal circuit information storage 170 to an external device when setting initial connection paths.

To be specific, the communication unit 160 may send information about an attribute of the internal circuit, a position connected to each of input/output terminals of the internal circuit, an attribute of a signal to be communicated via each of input/output terminals of the internal circuit, and/or another external circuit connected to each of input/output terminals of the internal circuit, etc.

When all of information about each internal circuit are stored in a system having variable paths, information to be sent via the communication unit 160 may include identification information to indicate an attribute of the internal circuit or polyhedral module device. Alternatively, when some of information about each internal circuit are stored in a system having variable paths, information to be sent via the communication unit 160 may include the rest of the information about each internal circuit together with identification information to indicate an attribute of the internal circuit or polyhedral module device.

Further, the communication unit 160 may receive a signal from another polyhedral module device adjacent to one outer face of the current module device and send the received signal to another outer face of the current module device.

The information to be sent via the communication unit 160 may further include signal transfer path information to indicate a path along which the signal travels, and the internal circuit connection information. The signal transfer path information may include identification information about the polyhedral module device and outer face identification information to indicate an outer face through which the signal has received.

For example, provided that cubic-shaped polyhedral module devices A, B, C are combined in this order, information generated about the polyhedral module device A may include identification information of the polyhedral module device A, identification information of a first outer face (facing the device B) of the device A and internal circuit connection information about the device A. In this connection, the information may be communicated between the devices A and B via the contact on the first outer face of the device A.

The information generated about the polyhedral module device A may be transferred to the polyhedral module device B which in turn, may send to the polyhedral module device C the identification information of the device A, the identification information of the first outer face (facing the device B) of the device A, identification information of a first outer face (facing the device A) of the device B, identification information of the device B, identification information of a second outer face (facing the device C) of the device B, and the internal circuit connection information about the device A. In this connection, the information may be communicated between the devices B and C via the contact on the second outer face of the device B.

In this connection, the device B may send the information from the device A via another outer face thereof not facing the device C. For example, the device B may send from the device A via a third outer face thereof not facing the device C to the device C the identification information of the device A, the identification information of the first outer face (facing the device B) of the device A, the identification information of the first outer face (facing the device A) of the device B, the identification information of the device B, identification information of the third outer face (not facing the device C) of the device B, and the internal circuit connection information about the device A.

That is, when the device B sends the information from the device A via the third outer face thereof not facing the device C, the resultant information reaching the device C may be the same as the resultant information when the device B sends the information from the device A via the outer face thereof facing the device C to the device C except for the identification information of the third outer face of the device B.

In this connection, the internal circuit connection information of the device A may be actual connection information of the internal circuit in the device A or may be identification information to indicate an attribute of the internal circuit therein or an attribute of the polyhedral module device A or may be a combination of the identification information and partial internal circuit connection information.

Upon receiving the information from the device B, the polyhedral module device C, specifically, a communication unit thereof may determine using the information from the device B the sequence of the polyhedral module devices and mutual-facing outer faces of the devices A, B, and C.

In this way, a communication unit of the polyhedral module device C may know the positions of the polyhedral module devices A and B. Thus, when the polyhedral module device C is to send a signal to the module device A, the polyhedral module device C may predetermine a signal path. To be specific, the polyhedral module device C may send the signal via a first outer face (facing the device B) of the device C, and via the first outer face (facing the device A) of the device B to the device A. In this connection, the fast signal transfer may be achieved and an unnecessary traffic may be prevented.

The communication unit 160 may be configured to filter signals input thereto and to output the filtered signals.

For example, when the polyhedral module device issuing the signal currently received from the communication unit is identical with the polyhedral module device issuing the signal previously outputted from the communication unit, the signal currently received from the communication unit may not be outputted from the communication unit.

The polyhedral module device may send a specific signal to all of adjacent polyhedral module devices and then each of all of the adjacent polyhedral module devices may receive the signal and then may send the signal to all of further adjacent polyhedral module devices except for the polyhedral module device originally issuing the specific signal. Thus, signal transmissions between the adjacent polyhedral module devices may highly increase.

In particular, when the number of the polyhedral module devices forming a target complete modular electronic modular assembly, signal transmissions between the adjacent polyhedral module devices may explode.

In order to solve this problem, when a first polyhedral module device receives the same signal multiple times from a second polyhedral module device, the first polyhedral module device may be configured to output only the first-received signal. In this connection, when the first-received signal is plural, only a signal with a shortest transmission path may be selected and outputted. In this way, the traffic explosion between the polyhedral module devices may be suppressed.

Alternatively, signal transmission may be limited to a predetermined time period. Out of the predetermined time period, the signal transmission may be disabled. In this way, the traffic explosion between the polyhedral module devices may be suppressed.

In this connection, it may be difficult to locate all transmission paths. This may be solved by repeating signal transmissions until each of the polyhedral module devices is located.

A combination sequence or position of the polyhedral module devices, orientations of the polyhedral module devices, connection information of the internal circuit in each of the polyhedral module devices may be known. This may allow a design of an overall circuit connection path which may allow connections between the switches 131 in the switch network 130 of each polyhedral module device to be adapted.

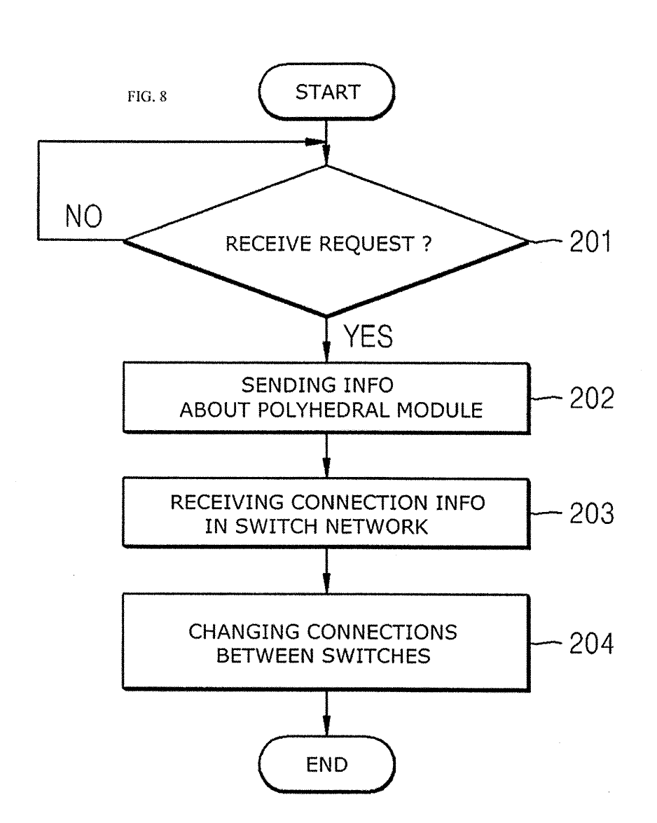

The changing operation of the connections between the switches 131 will be described with reference to FIG. 8 below in details.

When the user combines a target polyhedral module device into a complete modular electronic modular assembly, communication between the target polyhedral module device and an external system or another polyhedral module device configured to support adaption of the connections between the switches may be established. As used herein, the external system or another polyhedral module device configured to support adaption of the connections between the switches may be referred to as an “adaption-support external system”. Then, the adaption-support external system may request information about the internal circuit in the target polyhedral module device to the target polyhedral module device, especially, the communication unit in the target polyhedral module device (201).

The adaption-support external system may be embodied as a computer or dedicated terminal or web server or a communication terminal coupled to the server containing therein programs or information configured to support adaption of the connections between the switches. The present disclosure is not limited thereto.

The information transmission request signal may be sent via the fixed path as described above and the communication unit to the internal circuit information storage.

In this connection, as described above, the signal transmission path information may be included in the request signal and/or the response signal to allow the position and orientation of the polyhedral module device to be visible to the adaption-support external system and/or another polyhedral module device.

After the communication unit 160 receives the information transmission request signal, the communication unit 160 may be configured to send the internal circuit connection information in the internal circuit information storage 170 along the path information via an adjacent polyhedral module device to the adaption-support external system.

The internal circuit connection information may indicate actual connection in the internal circuit or may be identification information to indicate the attribute of the internal circuit or the polyhedral module device including the internal circuit, or a combination of the identification information and partial connection of the internal circuit.

The signal may be sent via all of the outer faces of the polyhedral module device. The present disclosure may not be limited thereto. Based on the signal transfer path information in the information transmission request signal, a position of the polyhedral module device may be determined. Based on the determination, a shortest path for the path may be determined to have a single outer face of the polyhedral module device. Thus, the signal may be sent via the single outer face.

For this, the signal to be sent may include transmission path information thereof such that the signal may travel along the path in the transmission path information.

Upon receipt of the signal, the adaption-support external system may determine a sequential position of each polyhedral module device based on information in the received signal. Further, the adaption-support external system may determine connections of the internal circuit of the polyhedral module device based on information in the received signal. Thus, based on the determinations, the adaption-support external system may configure connection paths in the switch network 130.

The configuration of the connection paths may be implemented in a hardware, software or a combination thereof. Further, a table indicating a relationship between the connection paths and combinations of the polyhedral module devices may be stored in the database. The relationship may be retrieved upon request.

The table indicating a relationship between the connection paths and combinations of the polyhedral module devices may be stored in the database. The switch controller may retrieve the relationship based on the combination of the polyhedral module devices which may be defined in the received information.

The relationship between the connection paths and combinations of the polyhedral module devices may be created by the expert manually or may be programmed using a dedicated computer.

When the relationship between the connection paths and combinations of the polyhedral module devices is created by the expert, the expert may upload the connection paths created by him/her onto the web server, which may be checked in a validity or a reliability thereof by another expert. Thus, the connection paths proved to have validity or reliability may be stored in the database.

When connection path information for the target polyhedral module device intended to be fitted into the modular device is not present in the database, the user may download from the web sever the connection path information for the target polyhedral module device based on a layout of the database.

When the connection paths are designed and stored and retrieved or extracted, the adaption-support external system may send a corresponding switch network connection information to each polyhedral module device. Thus, the polyhedral module device may receive the switch network connection information and transfer the same to the switch controller 150 of the polyhedral module device (203).

The switch network connection information may be sent from the adaption-support external system to each of all of the polyhedral module devices. The present disclosure may not be limited thereto. The adaption-support external system may be coupled only a single polyhedral module device. When the adaption-support external system sends the switch network connection information associated with the target polyhedral module device to the single polyhedral module device, the target polyhedral module device may receive the associated switch network connection information from the single polyhedral module device.

In this connection, each polyhedral module device may determine a location of another polyhedral module device while sending the internal circuit connection information thereof. Thus, based on the determined location, each polyhedral module device may set the transmission path along which

the switch network connection information travels. Thus, each polyhedral module device may send the switch network connection information along the set transmission path.

For example, when in FIG. 2, the polyhedral module device 100-1 is coupled to the adaption-support external system, the polyhedral module device 100-1 may be configured to be aware, using path information in internal circuit connection information from the polyhedral module device 100-5, that the polyhedral module device 100-5 resides in a combination sequence of the polyhedral module device 100-5, polyhedral module device 100-3, and polyhedral module device 100-1. Further, the polyhedral module device 100-1 may be configured to be aware of adjacent outer faces of the polyhedral module device 100-5, polyhedral module device 100-3, and polyhedral module device 100-1.

In this way, when the polyhedral module device 100-1 receives the switch network connection information associated with the target polyhedral module device 100-5 from the support external system, the polyhedral module device 100-1 may be configured to direct the switch network connection information not toward the polyhedral module device 100-2 but toward the polyhedral module device 100-3.

The switch controller 150 may be configured to change connections between the switches 131 or change a connection in each switch 131 in the switch network 130 based on the switch network connection information. In this way, the switch network 130 may be configured in a connect therein to comply with the switch network connection information (204).

Using the present polyhedral module device, the user may prepare a target polyhedral module device with a desired internal circuit, and may combine the same into the complete modular assembly. In this connection, the adaption of the connection paths in the modular assembly may be supported by the external adaptation-support system. Thus, the adaption of the connection paths in the modular assembly may be automatically realized merely by the user connecting the modular assembly to the external adaptation-support system. Thus, non-expert unfamiliar with the electronics may easily add, replace or upgrade the target functional module.

However, the present disclosure may not be limited thereto. The target polyhedral module device may be added, replaced or upgraded into the complete modular assembly without the by the external adaptation-support system.

That is, the user may learn internal circuit connection information for each polyhedral module device using a manual or guidance material. Then, the user may configure the connection paths manually. The user may connect each polyhedral module device to his/her computer and receive the internal circuit connection information via the communication unit 160 from the polyhedral module device. Then, the user may directly set a location of each polyhedral module device using the computer to configure connection paths in the switch network. Based on the connection path information, the user may connect polyhedral module devices and then resend connection path information and thereafter assemble polyhedral module devices.

In this connection, the user may design all connection paths, and may connect the communication unit 160 of each polyhedral module device to her/his computer using the designed connection paths, and send associated information. The signal transmission via the polyhedral module device to inform the path information may not be necessary.

The power supply 180 may be configured to supply the power to components of the polyhedral module device.

In the simplest way to supply the power, the power supply 180 may have a wireless charged battery which may supply the power thereof to the components after fully charged.

In another approach, a fixed power supply path may be provided in the polyhedral module device, via which the power is supplied.

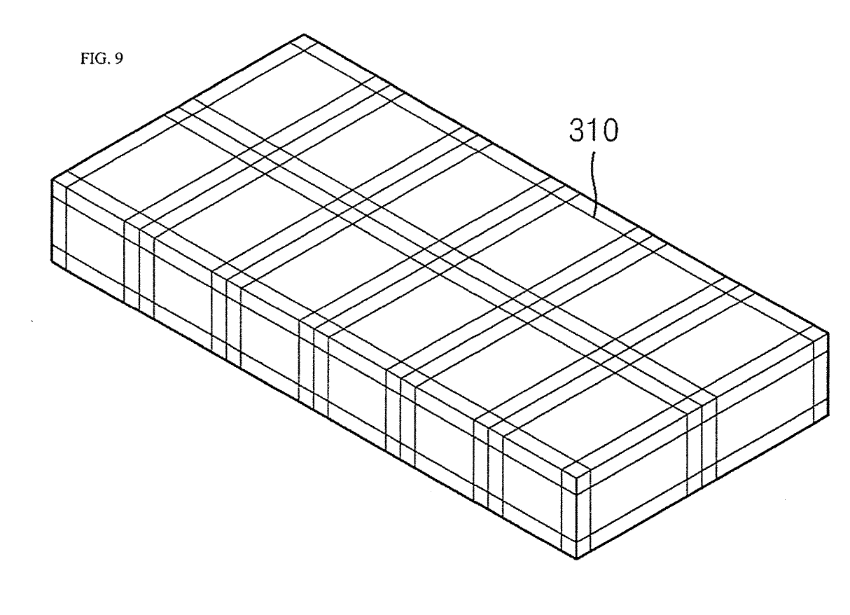

FIG. 9 shows fixed power supply paths for polyhedral module devices.

As shown in FIG. 9, power-supply fixed paths 310 may be coupled to the polyhedral module devices. The power-supply fixed paths 310 may run over all of the polyhedral module devices. The power-supply fixed paths 310 may realize the power supply to the modules devices.

In this connection, transferred currents or voltages may vary depending on the fixed paths. Thus, the power supply 180 may reduce or amplify the power to be transferred to come into a necessary range and then may supply the adjusted power to the components.

Alternatively, a bottom power supply mount may be provided which may be configured to mount the polyhedral module devices thereon. The bottom power supply mount may supply the power via the bottom thereof to the components.

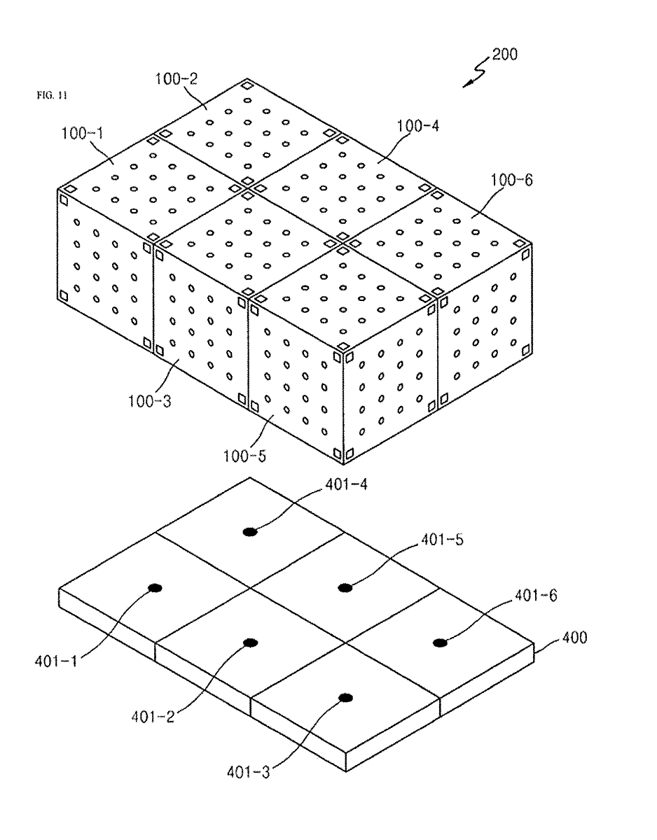

FIG. 11 shows a bottom power supply mount 400 to be coupled to the present polyhedral module devices to supply the power thereto.

The bottom power supply mount 400 may have power supply terminals 401-1, 401-2, 401-3, 401-4, 401-5, 401-6 (hereinafter, collectively 416) formed thereon. Each polyhedral module device may be coupled to each of the power supply terminals 401-1, 401-2, 401-3, 401-4, 401-5, 401-6. In this way, the power may be supplied via the power supply terminals to polyhedral module devices respectively.

The outer electrical contacts of the polyhedral module device may be directly connected to the power supply terminals 416 via the fixed paths.

The present polyhedral module devices may have the same size. The present disclosure may not be limited thereto. The polyhedral module devices may have different sizes.

As long as positions of outer electrical contacts of the polyhedral module devices are standardized, the shape and size of the polyhedral module devices may vary.

In another embodiment, a plurality of polyhedral module devices may be received in a single case. In this connection, this single case may act as a single polyhedral module device.

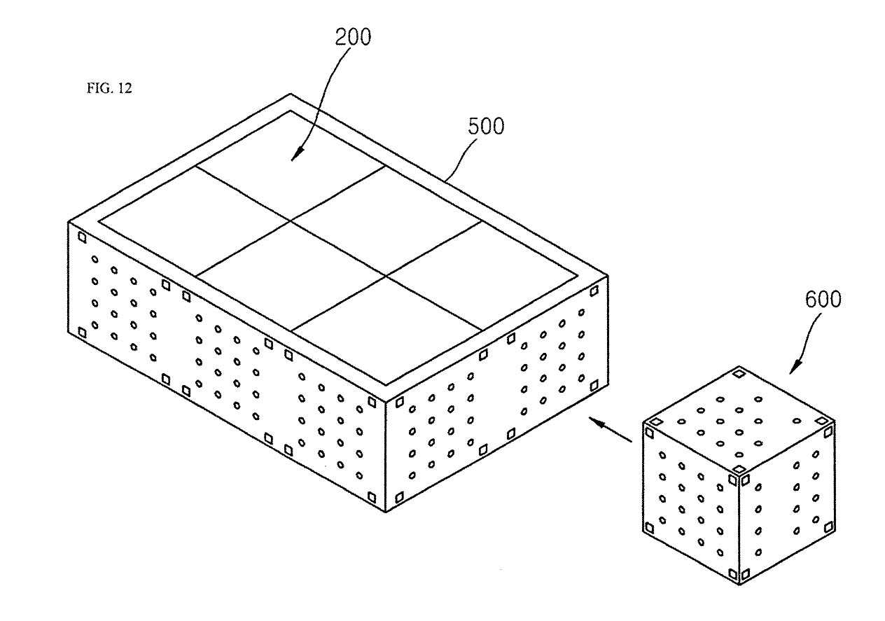

FIG. 12 shows a single external case 500 receiving therein a combination 200 of a plurality of polyhedral module devices.

In this connection, the external case 500 may receive the present polyhedral module devices. The single external case 500 receiving therein a combination 200 of a plurality of polyhedral module devices may act as a single larger polyhedral module device.

In this connection, the combination 200 of the polyhedral module devices may act as an internal circuit. In the case 500, inner contacts may be formed to contact the outer contacts of each polyhedral module device, which may act as the internal circuit mount. The internal circuit storage may store therein circuit information about the polyhedral module device combination 200 to indicate which internal circuit of which input and output terminals are connected to the outer electrical contacts of each polyhedral module device.

When the polyhedral module devices are combined and variable paths are set via the switch network, those paths may act as a signal path for the internal circuit in the combination 200.

The external case 500 may include components functionally corresponding to the switch controller 150, switch network 130, communication unit 160, and power supply 180 in each polyhedral module device.

The case 500 of the combination 200 of the polyhedral module devices may be functionally equivalent to each polyhedral module device. Thus, as shown FIG. 12, another polyhedral module device 600 may be coupled to the case 500 containing the combination 200.

The separate case 500 may allow the combination of the polyhedral module devices to act as an individual functional module which may be coupled to another polyhedral module device 600.

For example, the case 500 containing the combination 200 may act as a functional module corresponding to a MP3 function. This MP3 functional module may be added into the complete modular assembly such as a smartphone.

The manufacturer may produce an individual polyhedral module device to perform a specific function such as the MP3 functional module and sell the same. In an alternative, the combination of the polyhedral module devices may be produced and sold as a functional module to perform a larger scale function.

The user may purchase the individual polyhedral module device to perform a specific function such as the MP3 functional module or combination of the polyhedral module devices produced and sold as a functional module to perform a larger scale function. The user may use the individual polyhedral module device independently. Further, the individual polyhedral module device may be assembled into the modular assembly such as the smartphone. Thus, the individual polyhedral module device may be used in a single mode where only individual polyhedral module device may be used to perform its specific purposed function or may be used in an integrated mode where the individual polyhedral module device may be embedded in the modular assembly. Thus, the combination 200 of the polyhedral module devices as shown in FIG. 12 may be used as the single mode or integrated mode.

While the polyhedral module devices are assembled to achieve a single electronic modular assembly, the internal circuit in the single polyhedral module device may not be changed in the above embodiments.

However, the present disclosure may not be limited thereto. one polyhedral module device may constitute one electronic modular assembly. A plurality of internal circuits may be contained in one polyhedral module device and each internal circuit may be changed.

In this connection, the polyhedral module device may include a plurality of internal circuits and the connection between the input and output terminals of each internal circuit may be changed by the switch network.

In this connection, each internal circuit may be embodiment as a combination of a plurality of elements such as a capacitor, resistor, transistor, etc.

When a single polyhedral module device embodies a single electronic modular assembly, the outer electrical contacts 110, communication unit 160, and internal circuit information storage 170 in FIG. 5 may not be necessary.

Furthermore, in the above embodiments, the switch network 130 may change connection paths between the input and output of the internal circuit and the outer electrical contacts. The present disclosure may not be limited thereto. When a single polyhedral module device embodies a single electronic modular assembly, the switch network 130 may enable or disable a connection path between the input and output of each of a plurality of internal circuit.

The user may set connection paths in the switch network using information about a connection between input and output of each of a plurality of internal circuit in the polyhedral module device. Based on the connection paths, the switch control information may be inputted to the switch controller 150. Thus, the switch controller 150 may enable or disable switches 131 in the switch network 130 based on the switch control information to set the connection paths.

In this connection, setting of the connection paths in the switch network and generation of the switch control information may be performed using the external system having a separate program or database as described above.

When the single polyhedral module device embodies the complete electronic device having the various internal circuits, connection paths between the various internal circuits may be set in a similar manner to as in FIG. 2.

However, when a plurality of polyhedral module devices may form the complete modular assembly, each polyhedral module device may store therein internal circuit connection information or identification information thereof. When each polyhedral module device sends the information, switch network connection information may be generated based on the information. However, when the single polyhedral module device embodies the complete electronic device having the various internal circuits, the internal circuit connection information may not be stored in the module device. The user may input elements used in the internal circuit, and locations of the circuits and elements on the internal circuit mount 140, and thus switch network connection information may be generated based on the user inputs.

In the above embodiments, each polyhedral module device is connected to another module device or an external device using the outer electrical contacts 110 in a wired manner. The present disclosure is not limited thereto. The communications between the polyhedral module devices may be implemented in a wireless manner.

In this connection, the communication unit of each polyhedral module device may use a short range wireless communication such as Bluetooth.

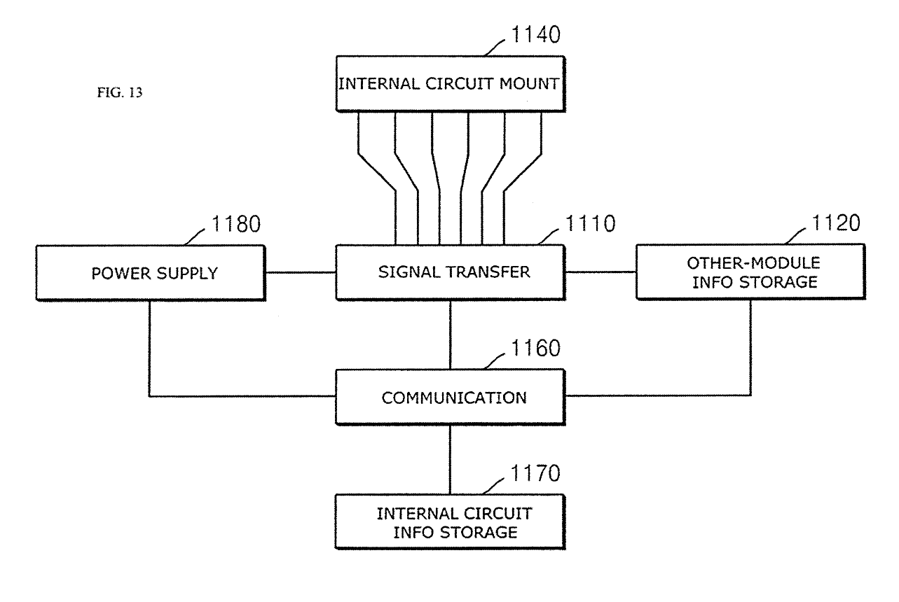

FIG. 13 shows a block diagram for explaining a configuration where the present polyhedral module device sends a signal wirelessly.

As shown in FIG. 13, the present polyhedral module device may include a signal transfer unit 1110, an other-module information storage 1120, an internal circuit mount 1140, a communication unit 1160, an internal circuit information storage 1170, and a power supply 1180.

The internal circuit mount 1140 may be similar to the internal circuit mount 140 in FIG. 5 to be connected to an input and an output of the internal circuit and to connect the internal circuit to another component.

The internal circuit information storage 1170 may be similar to the internal circuit information storage 170 in FIG. 5 to store therein internal circuit information.

In this embodiment where the wireless communication is employed, identification information about inputs and outputs of the internal circuit may be contained in the internal circuit information storage 1170.

In order to send a signal to a target input terminal of the internal circuit in a wireless manner, the identification information to indicate the target input terminal of the internal circuit may be needed.

The power supply 1180 may be similar to the power supply 180 in FIG. 5. Thus, details about the power supply 1180 may be omitted.

The other-module information storage 1120 may be configured to other-module information about a polyhedral module device other than the current or target module device.

The other-module information about a polyhedral module device other than the current or target module device may be needed because in a wireless signal transmission, a signal from an output of the internal circuit in each polyhedral module device may be input to which input terminal in which polyhedral module device should be informed.

Thus, the other-module information storage 1120 may have another polyhedral module device information including signal transmission path information to indicate which input terminal in which polyhedral module device should receive a signal from an output of the internal circuit in the target polyhedral module device in order to achieve the electronic modular assembly. The another polyhedral module device information may further include destination identification information to indicate a destination to which each signal transmission is directed.

The destination identification information may include identification information of each polyhedral module device and identification information of an input terminal of the internal circuit in the target polyhedral module device.

In another approach, the destination identification information may include identification information of the target polyhedral module device as a signal-transmitter and identification information of an output terminal of the internal circuit.

The destination identification information may act only to inform a final destination. Further, information about the internal circuit issuing the signal to the polyhedral module device may be already stored. Thus, the destination identification information may be based only on the polyhedral module device as a sender or may be based on only the polyhedral module device as a receiver.

In one embodiment, the destination identification information may be based on both the polyhedral module device as a sender and the polyhedral module device as a receiver.

The other-module information may be acquired by two following manners:

In a first approach, each polyhedral module device may receive directly information about another polyhedral module device from the external system containing each target internal circuit information.

For this, the user may access the external system such as a server used to provide polyhedral module device information and may input identification information of the target internal circuit and the target polyhedral module device including the target internal circuit. Then, the user may download from the external system the other-module information including the signal transmission path information and destination identification information, wherein the signal transmission path information indicates which path is used to transfer a signal in order to achieve an electronic modular assembly using the target polyhedral module device. The user may send the information about another polyhedral module device used to assemble the electronic modular assembly to the target polyhedral module device using a communicator with communication function with the polyhedral module device in a wireless or wired manner.

In a second approach, the external system may not store therein information about the polyhedral module device, but information in the internal circuit mount 1140 of the polyhedral module device may be sent to the external system which may use the information to generate the other-module information (as described above) in order to achieve the target electronic modular assembly.

In this connection, using the means configured to send a signal to each polyhedral module device, the internal circuit information request signal may be sent to each polyhedral module device. Then, each polyhedral module device may receive the internal circuit information request signal and, in a response, may send the target internal circuit information to the external system. Then, the adaption-support external system may set the connection in the switch based on the internal circuit information of each polyhedral module device.

The means configured to send a signal to each polyhedral module device may be a separate device. The present disclosure is not limited thereto. The means configured to send a signal to each polyhedral module device may be integrated into the polyhedral module device.

That is, in addition to the specific purposed internal circuit in the polyhedral module device, the means configured to communicate a signal between each polyhedral module device and the adaption-support external system may be included in the polyhedral module device. Thus, via the means, the polyhedral module device may communicate with the external system.

In this connection, when the means configured to communicate a signal between each polyhedral module device and the adaption-support external system may be included in the polyhedral module device, address information of the adaption-support external system may be contained in the polyhedral module device. In this way, a signal may be communicated between each polyhedral module device and the adaption-support external system in a wireless or wired manner.

The user may activate the communication between them by turning on a switch in the polyhedral module device and hence the polyhedral module device with a communication function may send an internal circuit information transmission request signal to another polyhedral module device. Then, the signal from each polyhedral module device may be sent to the external system.

In this connection, when the external system stores therein the internal circuit information of each polyhedral module device, the internal circuit information may not be sent to the external system but only the identification information of each polyhedral module device may not be sent to the external system.

Alternatively, when the external system stores therein some of the internal circuit information of each polyhedral module device, the other of the internal circuit information and the identification information of each polyhedral module device may not be sent to the external system.

The configuration that the means configured to communicate a signal between each polyhedral module device and the adaption-support external system is included in the polyhedral module device may be applied not only to the case in which each polyhedral module device transfers the signal in a wireless manner but also to the case in which each polyhedral module device transfers the signal via the outer electrical contacts as described above in a wired manner.

When each polyhedral module device transfers the signal via the outer electrical contacts as described above in a wired manner, in order to set a connection path, each polyhedral module device may send the internal circuit identification information thereof to the adjacent polyhedral module device, and the external system connected to one of the polyhedral module devices may receive the internal circuit identification information from the adjacent polyhedral module device. The present disclosure is not limited thereto. A separate polyhedral module device may act as a communication functional module to receive the signal from another polyhedral module device and then send the signal to the adaption support external system in a wired or wireless communication fashion, such that the adaption support external system may configure the connection path.

The transmission of the other-module information by the external system may be similar to configuring of the connection paths in the switch network in the polyhedral module device with the wired connection as described above.

Differently from using the outer electrical contacts in a wired manner, the polyhedral module devices may perform wireless signal communications. At this case, the polyhedral module device may dispense with a switch network configured to transfer the signal in a wired manner. However, in both the wireless and wired signal communications, the other-module information should be communicated wherein the other-module information may indicate, using the internal circuit information or identification information from each polyhedral module device, which input/output terminals in which polyhedral module device should be connected to input/output terminals in the internal circuit in each polyhedral module device.

To be specific, when it is configured such that only the identification information is received from each polyhedral module device, the generation of the other-module information may be based on the internal circuit information about the target polyhedral module device pre-stored in the database which may correspond to each identification information.

Information to indicate how to implement the circuit depending on the target electronic modular assembly and the polyhedral module device employed to achieve the assembly, that is, other-module information required for each polyhedral module device may be stored in the database. The other-module information may be retrieved from the database based on the received identification information.

Alternatively, the adaptation support external system may include a program or algorithm module configured to generate the other-module information. Thus, when the identification information about each polyhedral module device is inputted into the program or algorithm module, the program or algorithm module may generate the other-module information required to achieve the target electronic modular assembly and may send the other-module information to each polyhedral module device.

When it is configured such that not the identification information but the internal circuit information is received from the polyhedral module device, the generation of the other-module information may be equally achieved.

In this connection, the external system may dispense with the database to store therein the internal circuit information about each polyhedral module device.

The signal transfer unit 1110 may be configured to output the signal from each output of the internal circuit mounted on internal circuit mount 1140 via the communication unit 1160 to the external device and then may be configured to input a signal from the external device via the communication unit 1160 to an input terminal of the internal circuit mounted on internal circuit mount 1140.

When the signal transfer unit 1110 sends the signal to the communication unit 1160, the destination identification information of the signal may be added to the signal using the other-module information in the other-module information storage 1120. Thus, the communication unit 1160 may send the signal to the external device in a wireless communication protocol such as Bluetooth.

The communication unit 1160 may send the signal received from the signal transfer unit 1110 to the external device. Further, the communication unit 1160 may receive a signal whose destination is the polyhedral module device having the communication unit 1160 and then may send the signal to the signal transfer unit 1110.

When the signal transfer unit 1110 may receive the signal, the signal transfer unit 1110 may send the signal to the internal circuit on the internal circuit mount 1140 based on the destination identification information.

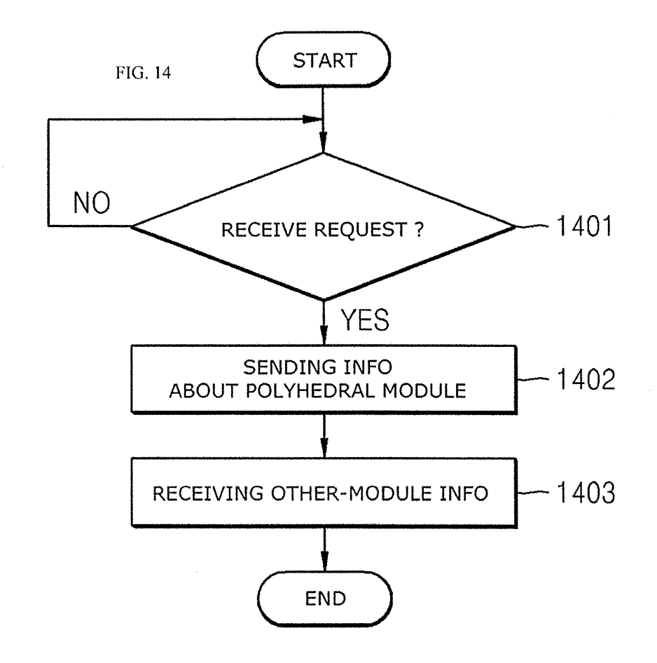

FIG. 14 shows one example of a method for setting a signal path when the present polyhedral module device transmits the signal wirelessly. To be specific, the method may set the signal path based on information received wirelessly.

First, the adaption support external system may send a request to each polyhedral module device of the internal circuit information of each polyhedral module device or identification information of each polyhedral module device. Upon the reception of the request (1401), the communication unit 1160 of each polyhedral module device may send the information in the internal circuit information storage 1170 to the adaption support external system in a wireless manner (1402).

In this connection, the information transmission may use a short range wireless communication technique.

Based on the internal circuit information or identification information of each polyhedral module device (or a combination of the identification information and partial internal circuit information), the adaption support external system may generate other-module information to indicate a signal path. The external system may send the other-module information to the communication unit and to the switch network. Each polyhedral module device may store the other-module information in the other-module information storage 1120.

When the other-module information is stored in each polyhedral module device, the signal transfer unit 1110 may send a signal based on the other-module information.

The setting of the connection paths in the switch network, and transferring of the signal using the set connection paths, and generation of the other-module information in a wireless manner, and transferring of the signal using the other-module information may be implemented by instruction codes stored in the computer readable medium. The computer readable medium may refer to all types of a storage device containing data which is readable by the computer. The computer readable medium may include, for example, ROM, RAM, CD-ROM, magnetic tape, floppy disk, optical data storage, etc. The computer readable medium may include a cloud or distributed storage system to be accessed via a network.

1. A polyhedral module device, the device comprising:
a body having multiple outer faces;
a plurality of outer electrical contacts on at least one outer face of the body;
an internal circuit mount disposed in the body;
a specific-purpose internal circuit mounted on the mount;
a switch network disposed in the body, the network having a plurality of switches, connections between the plurality of switches in the network being flexible, the switch network being configured to electrically connect the internal circuit to the outer electrical contact;
and a switch controller configured to change the connections between the plurality of switches,
wherein the change of the connections between the plurality of switches by the switch controller changes connection paths between the outer electrical contacts and the internal circuit.

2. The device of claim 1, wherein the polyhedral module device further comprises:
an internal circuit information storage configured to store therein internal circuit connection information to indicate connections of an input and an output of the internal circuit;
a communication unit configured to communicate with an external device via a fixed path, wherein the fixed path is formed between the electrical contact and the communication unit,
wherein in response to a receipt of the internal circuit connection information request from the external device, the communication unit is configured to send the internal circuit connection information from the storage via the fixed path to the external device.

3. The device of claim 2, wherein the communication unit is further configured to send signal transfer path information to the external device along with the internal circuit connection information, wherein the signal transfer path information indicates a path along which a single containing the internal circuit connection information travel.

4. The device of claim 3, wherein the signal transfer path information further includes first identification information about the polyhedral module device and second identification information to indicate an outer face associated with the fixed path.

5. The device of claim 1, wherein the polyhedral module device further comprises a communication unit configured to communicate with an external device via a fixed path, wherein the fixed path is formed between the electrical contact and the communication unit,
wherein the polyhedral module device defining a first polyhedral module device communicates with a further polyhedral module device defining a second polyhedral module device,
the communication unit is configured to receive a first signal from the second polyhedral module device and output a second signal, wherein the second signal includes, in addition to the first signal, identification information to indicate an outer face of the first polyhedral module device through which the first signal is input, and identification information of the first polyhedral module device, and identification information to indicate an outer face of the first polyhedral module device through which the second signal is output.

6. The device of claim 5, wherein the communication unit is configured to determine a position and orientation of the second polyhedral module device using the first signal, wherein the communication unit is configured to set a signal transmission path using the position and orientation of the second polyhedral module device in order to send a signal to the second polyhedral module device.

7. The device of claim 1, wherein the polyhedral module device further comprises physical couplers formed on the outer face of the polyhedral module device.

8. The device of claim 1, wherein the polyhedral module device further comprises:
an internal circuit information storage configured to store therein identification and/or connection information of the internal circuit; and
a communication unit configured to communicate with an external device via a fixed path, wherein the fixed path is formed between the electrical contact and the communication unit,
when the communication unit receives a request for the internal circuit identification and/or connection information from the external device, the communication unit is configured to send the identification and/or connection information of the internal circuit via the fixed path to the external device.

9. The device of claim 8, wherein the communication unit is further configured to send signal transfer path information along with the identification and/or connection information of the internal circuit, wherein the transfer path information indicates a path along which the identification and/or connection information of the internal circuit travels.

10. The device of claim 9, wherein the signal transfer path information includes identification information of the polyhedral module device and identification information of an outer face of the device via which the identification and/or connection information of the internal circuit is outputted.

11. A method for assembling a modular electronic assembly with a plurality of polyhedral module devices, wherein each polyhedral module device comprises:
a body having multiple outer faces;
a plurality of outer electrical contacts on at least one outer face of the body;
an internal circuit mount disposed in the body;
a specific-purpose internal circuit mounted on the mount;
a switch network disposed in the body, the network having a plurality of switches, connections between the plurality of switches in the network being flexible, the switch network being configured to electrically connect the internal circuit to the outer electrical contact;
a communication unit configured to communicate with an external device via a fixed path, wherein the fixed path is formed between the electrical contact and the communication unit,
an internal circuit information storage configured to store therein connection information of the internal circuit; and
a switch controller configured to change the connections between the plurality of switches,
wherein the change of the connections between the plurality of switches by the switch controller changes connection paths between the outer electrical contacts and the internal circuit,
wherein the method comprises:
receiving, by the communication unit, a request for the internal circuit connection information from the external device;
sending, by the communication unit, signal transfer path information along with the connection information of the internal circuit to the external device, wherein the transfer path information indicates a path along which the connection information of the internal circuit travels;
receiving, by the communication unit, from the external device, connections between the plurality of switches configured based on the signal transfer path information and the connection information of the internal circuit; and
changing, by the switch controller, actually changing the connections between the plurality of switches based on the received connections between the plurality of switches from the external device.

12. The method of claim 11, wherein the signal transfer path information includes identification information of the polyhedral module device and identification information of an outer face of the device via which the connection information of the internal circuit is outputted.

13. The method of claim 11, wherein the assembly includes a first polyhedral module device and a second polyhedral module device communicating with each other, wherein the method comprises:
receiving a first signal from the first polyhedral module device to the second polyhedral module device; and
outputting a second signal by the second polyhedral module device, wherein the second signal includes, in addition to the first signal, identification information to indicate an outer face of the second polyhedral module device through which the first signal is input, and identification information of the second polyhedral module device, and identification information to indicate an outer face of the second polyhedral module device through which the second signal is output.

14. The method of claim 13, further comprising:
determining a position and orientation of the first polyhedral module device using the first signal by the second polyhedral module device; and
setting a signal transmission path using the position and orientation of the first polyhedral module device in order to send a signal to the first second polyhedral module device.

15. A method for assembling a modular electronic assembly with a plurality of polyhedral module devices, wherein each polyhedral module device comprises:
a body having multiple outer faces;
a plurality of outer electrical contacts on at least one outer face of the body;
an internal circuit mount disposed in the body;
a specific-purpose internal circuit mounted on the mount;
a switch network disposed in the body, the network having a plurality of switches, connections between the plurality of switches in the network being flexible, the switch network being configured to electrically connect the internal circuit to the outer electrical contact;
a communication unit configured to communicate with an external device via a fixed path, wherein the fixed path is formed between the electrical contact and the communication unit,
an internal circuit information storage configured to store therein identification information of the internal circuit; and
a switch controller configured to change the connections between the plurality of switches,
wherein the change of the connections between the plurality of switches by the switch controller changes connection paths between the outer electrical contacts and the internal circuit,
wherein the method comprises:
receiving, by the communication unit, a request for the internal circuit identification information from the external device;
sending, by the communication unit, signal transfer path information along with the identification information of the internal circuit to the external device, wherein the transfer path information indicates a path along which the identification information of the internal circuit travels;
receiving, by the communication unit, from the external device, connections between the plurality of switches configured based on the signal transfer path information and the identification connection information of the internal circuit; and
changing, by the switch controller, actually changing the connections between the plurality of switches based on the received connections between the plurality of switches from the external device.

16. The method of claim 15, wherein the signal transfer path information includes identification information of the polyhedral module device and identification information of an outer face of the device via which the identification information of the internal circuit is outputted.

17. The method of claim 15, wherein the assembly includes a first polyhedral module device and a second polyhedral module device communicating with each other, wherein the method comprises:
receiving a first signal from the first polyhedral module device to the second polyhedral module device; and
outputting a second signal by the second polyhedral module device, wherein the second signal includes, in addition to the first signal, identification information to indicate an outer face of the second polyhedral module device through which the first signal is input, and identification information of the second polyhedral module device, and identification information to indicate an outer face of the second polyhedral module device through which the second signal is output.

18. The method of claim 17, further comprising:
determining a position and orientation of the first polyhedral module device using the first signal by the second polyhedral module device; and
setting a signal transmission path using the position and orientation of the first polyhedral module device in order to send a signal to the first second polyhedral module device.

19. A polyhedral module device as a member of a modular electronic assembly, wherein the device comprises:
a body;
a specific-purposed internal circuit in the body;
an internal circuit mount to mount the internal circuit in the body;
an internal circuit information storage to store therein information about the internal circuit;
an other-module information storage configured to store therein other-module information, wherein the other-module information includes signal transmission path information and destination identification information, wherein the signal transmission path information indicates which path is used to send a signal output from an output of the internal circuit in order to operate the electronic modular assembly, and the destination identification information indicates a destination to which the signal is directed;
a communication unit configured to communicate with another device wirelessly; and
a signal transfer unit configured to add the other-module information in the other-module information storage to the signal from the output of the internal circuit and to transfer the signal to the communication unit.

20. A method for assembling a modular electronic assembly with a plurality of polyhedral module devices, wherein each polyhedral module device comprises:
a body;
a specific-purposed internal circuit in the body;
an internal circuit mount to mount the internal circuit in the body;
an internal circuit information storage to store therein information about the internal circuit;
an other-module information storage configured to store therein other-module information, wherein the other-module information includes signal transmission path information and destination identification information, wherein the signal transmission path information indicates which path is used to send a signal output from an output of the internal circuit in order to operate the electronic modular assembly, and the destination identification information indicates a destination to which the signal is directed;
a communication unit configured to communicate with another device wirelessly; and
a signal transfer unit configured to add the other-module information in the other-module information storage to the signal from the output of the internal circuit and to transfer the signal to the communication unit,
wherein the method comprises:
receiving, by the communication unit, a request of the internal circuit connection information;
sending, by the communication unit, the internal circuit connection information wirelessly;
receiving the other-module information configured based on the internal circuit connection information; and
adding, by the signal transfer unit, the other-module information in the other-module information storage to the signal from the output of the internal circuit and transferring the signal to the communication unit.

21. A polyhedral module device comprising:
a body having multiple outer faces;
an internal circuit mount disposed in the body;
a specific-purpose internal circuit mounted on the mount;
a switch network disposed in the body, the network having a plurality of switches, connections between the plurality of switches in the network being flexible;
a switch controller configured to change the connections between the plurality of switches and/or change a connection in each switch based on switch control information;
wherein the change of the connection in each switch enables or disables a connection between input and output terminals of the internal circuit.

22. A method for assembling a modular electronic assembly with a plurality of polyhedral module devices, wherein each polyhedral module device comprises:
a body having multiple outer faces;
an internal circuit mount disposed in the body;
a specific-purpose internal circuit mounted on the mount;
a switch network disposed in the body, the network having a plurality of switches, connections between the plurality of switches in the network being flexible;
a switch controller configured to change the connections between the plurality of switches and/or change a connection in each switch based on switch control information;
wherein the change of the connection in each switch enables or disables a connection between input and output terminals of the internal circuit,
wherein the method comprises:
receiving the switch control information; and
changing the connection in each switch based on the switch control information to enable or disable a connection between the input and output terminals of the internal circuit.

23. A computer readable medium including instructions which are executed by a computer to allow the computer to perform the method of claim 11.
